(19) United States
(12) Patent Application Publication
(10) Pub. No.: US 2014/0377915 A1
(43) Pub. Date: Dec. 25, 2014

(54) Pre-mold for a magnet semiconductor assembly group and method of producing the same

(71) Applicant: Infineon Technologies AG, Neubiberg (DE)

(72) Inventor: Klaus ELIAN, Alteglofsheim (DE)

(21) Appl. No.: 13/923,191

(22) Filed: Jun. 20, 2013

(51) Int. Cl. H01L 43/12; H01L 43/02

(52) U.S. Cl. CPC H01L 43/12; H01L 43/02
USPC 438/127; 257/421

(57) ABSTRACT

A method of manufacturing pre-molds for a magnet semiconductor assembly group is provided, wherein the method comprises forming a plurality of permanent magnetizable elements on a carrier structure in a sensor-free area of the carrier structure by applying a permanent magnetizable molding material on the carrier structure.

### BACKGROUND OF THE INVENTION

1. Field of the Invention

The present invention relates to a pre-mold for a magnet semiconductor assembly group and methods of manufacturing such pre-mold.

2. Description of the Related Art

In the art a plurality of semiconductor devices and housings of the same are known. Some of such semiconductor devices comprise a housing defining a cavity, a magnetic sensor chip disposed in the cavity, and molding material covering the magnetic sensor chip and substantially filling the cavity. Such semiconductor devices include motors, loudspeakers, microphones and magnetic sensors of the automotive technology. All of these devices comprise permanent magnets which are connected to carrier substrates by adhesives or by screwing techniques. For example sensors of these devices, e.g. so called back-bias magnet sensors, are glued to the backside of the carrier structure.

However, there is still potential room to improve the manufacturing of semiconductor devices comprising magnetic structures or magnetizable elements.

### SUMMARY OF THE INVENTION

There may be a need to provide pre-molds for a magnet semiconductor assembly group and methods of manufacturing such pre-molds which are simple to perform and which allow for a high yield of magnet semiconductor assembly groups.

According to an exemplary aspect a method of manufacturing pre-molds for a magnet semiconductor assembly group is provided, wherein the method comprises forming a plurality of permanent magnetizable elements on a carrier structure in a sensor-free area of the carrier structure by applying a permanent magnetizable molding material on the carrier structure.

According to another exemplary aspect a pre-mold array for magnet semiconductor assembly groups is provided, wherein the pre-mold comprises a carrier structure, and a plurality of permanent magnetizable elements of a permanent magnetizable material formed onto the carrier structure by an adhesive-free process, wherein the plurality of permanent magnetizable elements of a permanent magnetizable material are formed in a sensor-free area of the carrier structure.

According to an exemplary aspect a method of manufacturing a magnet semiconductor assembly group is provided, the method comprising forming a plurality of permanent magnetizable elements of a permanent magnetizable molding material on a carrier structure, placing a semiconductor at at least one of the plurality of permanent magnetizable elements of a permanent magnetizable material.

The use of a method of manufacturing a pre-mold for a magnet semiconductor assembly group may allow for a simple and efficient method for manufacturing a pre-mold. In particular, it may be possible that during the forming of the permanent magnetizable elements by depositing permanent magnetizable material the limitation with respect to the processing or forming condition may be reduced, since the permanent magnetizable elements are formed before a semiconductor chip or sensor is arranged or placed onto the carrier structure. Furthermore, the provision of a pre-mold or a plurality of pre-molds which already comprise permanent magnetizable elements of permanent magnetizable material may allow for a simplified further processing of the pre-mold(s) or manufacturing of a magnet semiconductor assembly group, since respective semiconductors or sensors may be easy to assemble afterwards. Moreover, the yield of magnet semiconductor assembly groups may be increased, since the manufactured pre-molds may be optically inspected and only good or fault-free permanent magnetizable elements may be assembled with semiconductors so that semiconductors may be saved.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIGS. 1A-1I show a magnet semiconductor assembly group in various stages of manufacture according to an exemplary embodiment.

FIG. 2A shows a schematic view of an example of a shape of a pre-mold according to an exemplary embodiment.

FIG. 2B shows a schematic view of an example of shape of a pre-mold according to another exemplary embodiment.

FIG. 2C shows a schematic view of an example of shape of a pre-mold according to yet another exemplary embodiment.

FIG. 3A shows a schematic view of an example of a carrier structure and a semiconductor which can be used in a magnet semiconductor assembly group.

FIG. 3B shows a schematic view of another example of a carrier structure and a semiconductor which can be used in a magnet semiconductor assembly group.

FIG. 3C shows a schematic view of yet another example of a carrier structure and a semiconductor which can be used in a magnet semiconductor assembly group.

FIG. 3D shows a schematic view of still yet another example of a carrier structure and a semiconductor which can be used in a magnet semiconductor assembly group.

### DESCRIPTION OF FURTHER EXEMPLARY EMBODIMENTS

In the following, further exemplary embodiments of the method and of the pre-mold array and of a magnet semiconductor assembly group will be explained. It should be noted that embodiments described in the context of the method may also be combined with embodiments of the pre-mold array and with embodiments of the semiconductor assembly group and vice versa.

According to another exemplary aspect a pre-mold array is provided, wherein the pre-mold array is produced according to the method according to an exemplary aspect.

In particular, the applying of the permanent magnetizable molding material may be a direct applying, i.e. an applying where the molding material is applied in a liquid, fluid or at least plastic state to the carrier substrate and not in a solidified state. For example, the carrier structure may be a leadframe, a circuit board, a printed circuit board or flexible print material. For example, the carrier structure may be an electric conducting carrier structure, e.g. an electric conductive lead frame.

The forming process may be any process at which the form or shape of the element, e.g. the shape of the permanent magnetizable element, is created or produced during the forming process. Examples for a forming process may be a molding process which is suitable to achieve a permanent magnetizable element of a permanent magnetizable material, for example a forming or molding process using a form or a forming or molding process performed by just extruding the molding material onto the carrier substrate without the use of any specific form. For example, an injection molding process, like a thermoplast or thermoset injection molding process, may be used. In particular, the forming of the plurality of permanent magnetizable elements may be a direct forming onto the carrier, e.g. the permanent magnetizable elements may be formed on the carrier substrate without any adhesives. Thus, the direct forming may have to be distinguished from an indirect arranging or placing of already molded permanent magnetizable elements onto a carrier which are then fixed to the carrier afterwards, e.g. by adhesives.

It should be noted that the permanent magnetizable elements may have any desired shape or form, e.g. the shape may correspond to a cuboid, a cube, a truncated pyramid which may be either massive or comprises at least one geometric feature like a hole, a recess, a notch, a dent or the like. In particular, each of the formed permanent magnetizable elements of permanent magnetizable material may be adapted to accommodate a semiconductor chip or sensor. For example, each of the plurality of permanent magnetizable elements may form a main body of one or a single pre-mold or at least a portion of the main-body of the main body. In particular, the permanent magnetizable elements may be formed in a sensor-free or semiconductor-free area of the carrier structure.

According to another exemplary aspect a method of manufacturing magnet semiconductor assembly groups is provided, wherein the method comprises forming a plurality of magnetic elements as pre-mold structures on a carrier structure in a semiconductor chip-free area of the carrier structure by applying a magnetic molding material on the carrier structure and subsequently arranging a plurality of semiconductor chips on the carrier structure, each of which being positioned at an assigned one of the plurality of magnetic elements to thereby form the magnet semiconductor assembly groups. In this context the term “magnetic element” may particularly denote an element which is magnetizable or which is already magnetized.

The term “forming” or “forming process” may particularly denote any process by which the form or shape of the element, e.g. the shape of the permanent magnetizable element, is created or produced during the forming process, e.g. a molding or molding process.

The term “sensor-free area” may particularly denote a specific area of a carrier structure on or at which no sensor is present. For example, the area may be defined with respect to a top view on a plane like or quasi-two-dimensional carrier structure. It should be noted that this definition of the term “sensor-free area” in particular covers the case that opposing main surfaces of a carrier structure are sensor-free in the respective area. In other words a sensor-free area of a carrier structure may be an area at which no sensors are arranged above and below the carrier structure. However, the respective area may be adapted, suitable or intended for arranging a sensor on that area afterwards. For example, after forming or molding a permanent magnetizable element of a permanent magnetizable material a sensor of an assembly group may be arranged or formed in the former sensor-free area above or below or attached to the molded permanent magnetizable element. The term “semiconductor-free area” may particularly denote a specific area of a carrier structure on or at which no semiconductor is present.

The term “pre-mold” or “pre-mold package” may particularly denote an unit or element comprising a molded permanent magnetizable element or package which may be adapted to accommodate a semiconductor, semiconductor chip, IC chip or sensor but yet does not comprise the semiconductor, semiconductor chip, IC chip or sensor. Thus, it may be said that the pre-mold forms a kind of housing which is molded beforehand and which is afterwards used to accommodate a semiconductor, semiconductor chip, IC chip or sensor.

The term “assembly group” may particularly denote a group of components or permanent magnetizable elements assembled together and connected to each other to form a device or system adapted to perform a specific function or operation, e.g. a so called microelectromechanical system (MEMS). The specific term “magnet semiconductor assembly group” may particularly denote an assembly group comprising at least one magnet or permanent magnetizable element and at least one semiconductor, like an IC chip or a sensor. Examples for such a magnet semiconductor assembly group may be a MEMS Hall sensor or a MEMS microphone.

The term “permanent magnetizable” may particularly denote the characteristic of any material that this material can be permanently magnetized by stimulation or excitation of an external field. In other words the term “permanent magnetizable” may denote the characteristic of a material that the material or an element formed by that material has a remanence or remanent magnetization after stimulation. Thus, material which is only paramagnetic may not fall under the definition of “permanent magnetizable”. In particular, the permanent magnetizable material may be a one compound material or may be a material comprising two or more compounds, e.g. comprising a main compound which may be moldable and a tracer or filler compound which provides the magnetising effect. For example, the permanent magnetizable material may comprise or may be ferromagnetic material like iron, nickel or cobalt or a respective alloy or may be a plastic material which can form a permanent magnet.

The term “permanent magnetizable element” or “permanent magnetizable element structure” may particularly denote any structure comprising one (in particular more than one) material and having a predetermined shape. For example, the permanent magnetizable element may comprise or may be formed by a mixture of two compounds, e.g. a main moldable compound in which a permanent magnetizable filler or trace compound is mixed. In particular, the permanent magnetizable element may be a composite or composite structure comprising at least one permanent magnetizable compound.

The term “molding material” may particularly denote a material which is suitable to be molded in a molding or casting process. In particular, a molding material may be viscous, plastic or liquid so that it can be molded or casted.

According to an exemplary embodiment of the method at least one of the plurality of permanent magnetizable elements is a three dimensional element, wherein the extension of the element is in a first dimension in the range between 2.5 mm and 25 mm, in a second dimension in the range between 2.5 mm and 25 mm and in a third dimension in the range between 2.5 mm and 25 mm.

In particular, the extension of the element is in a first dimension in the range between 5.0 mm and 15 mm, in a second dimension in the range between 5.0 mm and 15 mm and in a third dimension in the range between 5.0 mm and 15 mm. For example, permanent magnetizable element may be of a size of at least 5 mm×5 mm×5 mm. Preferably the size of the at least one permanent magnetizable element may be 7 mm×7 mm×7 mm. In particular, all of the plurality of magnetizable elements of a magnetizable material may have the same or substantially the same size. For example, the size of the at least one of the plurality of permanent magnetizable elements may be adapted to accommodate sensors of a specific size. The provision of such relatively large permanent magnetizable elements of permanent magnetizable material may allow to provide magnets or magnet bodies generating a relatively strong magnetic field. For example, the remanence or remanent magnetization may be in the range of 100 mT to 1000 mT, more particular in the range of 250 mT to 600 mT. However, also a lower or a higher remanence may be possible depending on the permanent magnetizable material and/or size of the permanent magnetizable elements. Furthermore, it may be possible to arrange or place a relatively large semiconductor or sensor at the permanent magnetizable elements.

According to an exemplary embodiment of the method the permanent magnetizable material comprises electric conductive material.

In particular, the specific electric conductivity of the conductive material may be above a given threshold value, in particular it may be above 1·10⁵ S/m or even above 1·10⁶ S/m. The use of an electric conductive material may allow for a simple and efficient conducting or connection of sensor which may be placed on the permanent magnetizable elements.

According to an exemplary embodiment the method further comprises forming an electric insulating layer between the carrier structure and at least one of the plurality of permanent magnetizable elements of a permanent magnetizable material.

For example, the electric insulating layer or an insulating structure may be formed on the carrier substrate before the permanent magnetizable elements are formed on the carrier substrate.

In particular, several or all of the plurality of permanent magnetizable elements may be electrically insulated from the carrier structure by providing insulating layers or structures. Thus, it may be possible to ensure that no short is generated or formed between the permanent magnetizable elements and the carrier structure.

According to an exemplary embodiment the method further comprises singularizing the plurality of permanent magnetizable elements.

According to an exemplary embodiment the method further comprises magnetizing at least one of the plurality of permanent magnetizable elements.

In particular, the magnetizing may be performed before or afterwards of singularizing the plurality of permanent magnetizable elements. In case it is performed beforehand it may be easy to provide the same magnetisation to all of the permanent magnetizable elements. In case it is performed afterwards it may allow that the singularized permanent magnetizable elements are exposed to different magnetizations. Due to the magnetizing or magnetization process the permanent magnetizable elements become magnetized elements, i.e. elements having a permanent magnetization or remanent magnetization.

According to an exemplary embodiment of the method at least one of the plurality of permanent magnetizable elements of a permanent magnetizable material comprises a recess.

In particular, the recess may be formed on the upper side of the carrier. The recess may have a form or shape which is adapted to generate or achieve a desired magnetic field at or close to the permanent magnetizable or magnetized element. Additionally, the recess may be used to insert or arrange a semiconductor, semiconductor chip, IC chip or sensor into the recess. It should be noted that the term “recess” may particularly denote not only an area or cavity free of any material, but may be interpreted in a broader sense, namely in the sense that in the recess no permanent magnetizable material is present while other material may be present. Thus, the term “recess” may refer to empty recesses or material filed recesses as long as the material filling the recess is not permanent magnetizable and/or not magnetic. For example, the recess or a portion of the recess may have a cuboid, a cylindrical or pyramidal shape or form.

According to an exemplary embodiment of the method the at least one of the plurality of permanent magnetizable elements comprises a hole.

In particular, the hole may be a blind or through hole and/or may have a circular or elliptical cross section. Thus, the permanent magnetizable element of permanent magnetizable material may form a kind of hollow cylinder. Such a hollow cylinder may be suitable to form a magnet field which is zero or close to zero in the recess or blind or through hole.

According to an exemplary embodiment of the method at least one of the plurality of permanent magnetizable elements is formed on a first main surface of the carrier structure and comprises a portion which extends through the carrier structure onto a second opposite main surface of the carrier structure.

According to an exemplary embodiment the method further comprises arranging at least one semiconductor chip at the plurality of permanent magnetizable elements of a permanent magnetizable material.

In particular, the at least one semiconductor chip or IC chip may form or may be part of a sensor or sensor module or even form the sensor. For example, a sensor or sensor chip is arranged. After the IC chip or semiconductor chip is arranged, attached or placed at the permanent magnetizable element, e.g. at a flat top or in a recess, the IC chip or semiconductor chip may be electrical connected to contacts, pads or terminals of the carrier structure or an external structure. The electrical connection may be formed by wire bonding, for example. In particular, the at least one semiconductor chip may be arranged or placed on an opposite side of the carrier structure with respect to the permanent magnetizable element. For example, the permanent magnetizable element may be formed or molded on a first main surface of the carrier substrate and the at least one semiconductor chip may be arranged afterwards on a second main surface opposite to the first main surface. In particular, the arranged semiconductor chip may be surrounded by a portion of one permanent magnetizable element, e.g. circumferential surrounded. For example, a portion of the permanent magnetizable element may pass through the carrier structure and may build a circumferential structure surrounding the arranged semiconductor chip.

In particular, the one or more semiconductor chips may be non-packaged semiconductor chips or sensors or may be part of an already packaged sensor or sensor module.

According to an exemplary embodiment the method further comprises encapsulating the at least one semiconductor chip or IC chip arranged to the plurality of permanent magnetizable elements.

For example the encapsulating may be performed by molding or casting a resin or similar pourable or viscous compound. In particular, at least one of the plurality of permanent magnetizable elements, several of the plurality of permanent magnetizable elements or all of the plurality of permanent magnetizable elements may be encapsulated.

According to an exemplary embodiment of the pre-mold array or batch each of the plurality of permanent magnetizable elements of a permanent magnetizable material is a three dimensional element, wherein the extension of the element is in a first dimension in the range between 2.5 mm and 25 mm, in a second dimension in the range between 2.5 mm and 25 mm and in a third dimension in the range between 2.5 mm and 25 mm.

In particular, the extension of the element is in a first dimension in the range between 5.0 mm and 15 mm, in a second dimension in the range between 5.0 mm and 15 mm and in a third dimension in the range between 5.0 mm and 15 mm. For example, the permanent magnetizable element may be of a size of at least 5 mm×5 mm×5 mm.

According to an exemplary embodiment of the pre-mold array or batch the carrier structure is an electrically conductive carrier structure.

According to an exemplary embodiment of the pre-mold array or batch the permanent magnetizable material is an electrically conductive material.

Alternatively, the permanent magnetizable material may be an electrically insulating material.

According to an exemplary embodiment the pre-mold array or batch further comprises an electrically insulating layer arranged between the electrically conductive carrier structure and each of the plurality of permanent magnetizable elements of permanent magnetizable material.

According to an exemplary embodiment of the pre-mold array or batch the permanent magnetizable material is electrically conductive.

According to an exemplary embodiment of the pre-mold array or batch the permanent magnetizable material is electrically insulating.

In particular, the permanent magnetizable material may be a plastic or synthetical material. For example, polyphenylenesulfide (PPS) or similar material may be used as the permanent magnetizable material. PPS may be a suitable material, since it is permanent magnetizable and temperature stable up to temperatures above 200° C., so that wire bonding of the pre-mold or pre-molded package may be performed afterwards without destroying or degrading the permanent magnetizable elements or magnetization of the magnetized elements.

According to an exemplary embodiment of the pre-mold array or batch the at least one of the plurality of permanent magnetizable elements comprises an undercut engaging behind the carrier structure.

The term “undercut” or “back-tapering” may particularly denote a structure or permanent magnetizable element of a structure which engages behind or grips around another structure. Thus, the structure may not easily be removed or detached from the another structure afterwards. In particular, no glue or adhesive may be necessary when using such an undercut or back-tapering. Such an undercut or undercutting structure may for example be produced or formed when molding a moldable or molding material through a hole or slit of a carrier or the carrier structure and the moldable material spreads out behind the hole or slit.

Summarizing a gist of an exemplary embodiment may be seen in providing a pre-mold or pre-mold array and a method of producing or manufacturing the same, wherein the pre-mold comprises a permanent magnetizable or even magnetized element of a permanent magnetizable material formed on a carrier structure while semiconductors or sensors which use the magnetic field generated by the magnetized element afterwards are not yet attached to the pre-mold. The carrier structure comprising the permanent magnetizable elements may then be further processed by magnetizing before or afterwards a singularizing and/or placing of semiconductor chips or IC chips has taken place. In particular, a pre-mold comprising a magnetic cavity and forming a permanent magnetizable element of a magnetic cavity package may be provided which may serve for packaging bare semiconductor or silicon chips or pre-packed sensors. The permanent magnetizable elements of permanent magnetizable material may provide large back-bias magnets for magnet semiconductor assembly groups in size and with respect to the strength of the magnetic field as well. In particular, a plurality of permanent magnetizable elements may be formed together in a single step, e.g. by molding, onto a carrier structure, like a leadframe or printed circuit board (PCB). The permanent magnetizable elements of permanent magnetizable material may have any desirable form or shape. In particular, the provision of a pre-mold may allow for an improved shaping of the magnet due to its simplified design.

### DETAILED DESCRIPTION OF THE FIGURES

The above and other objects, features and advantages of the present invention will become apparent from the following description and the appended claims, taken in conjunction with the accompanying drawings, in which like parts or elements are denoted by like reference numbers.

The illustration in the drawing is schematically and not necessarily to scale.

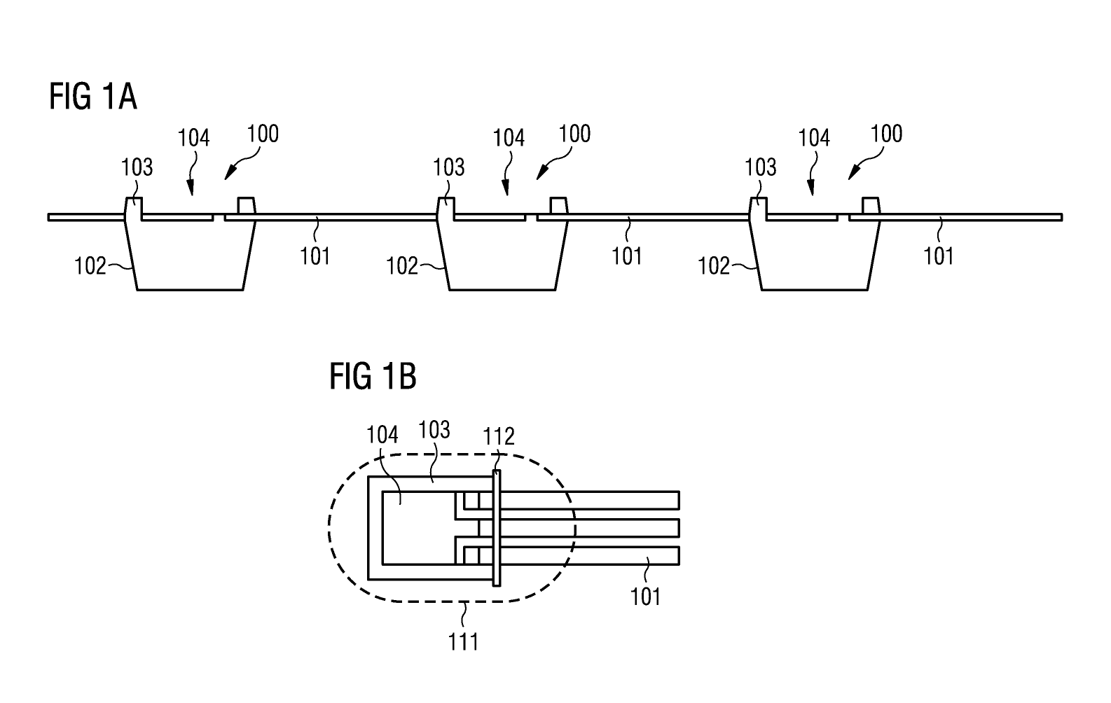

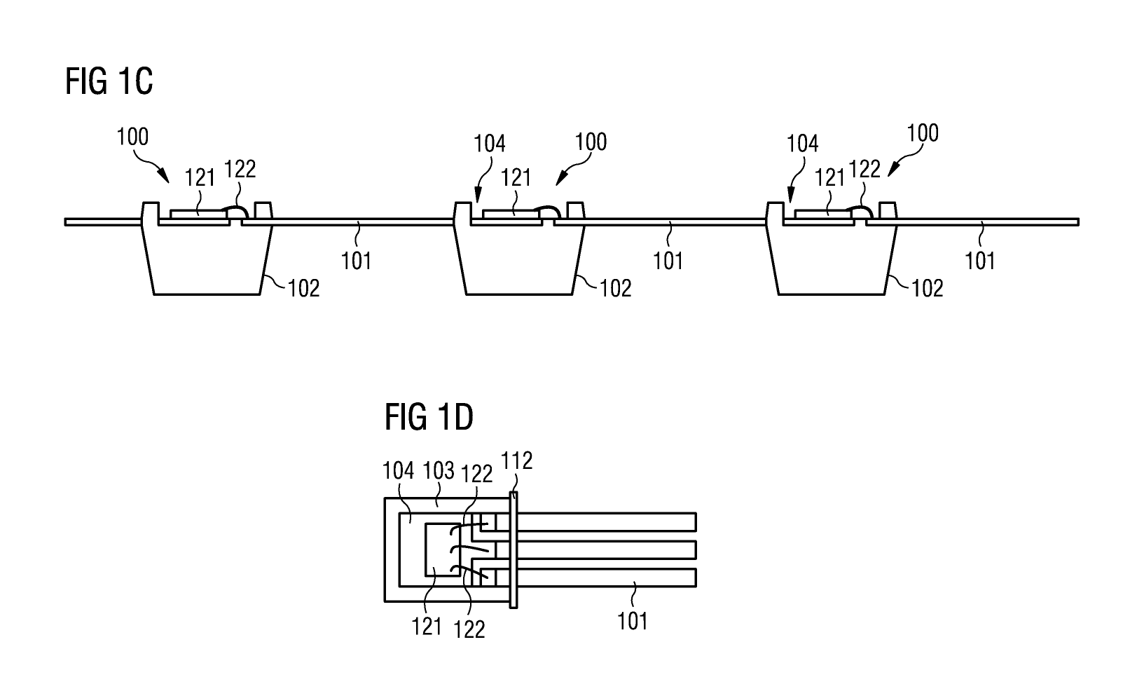

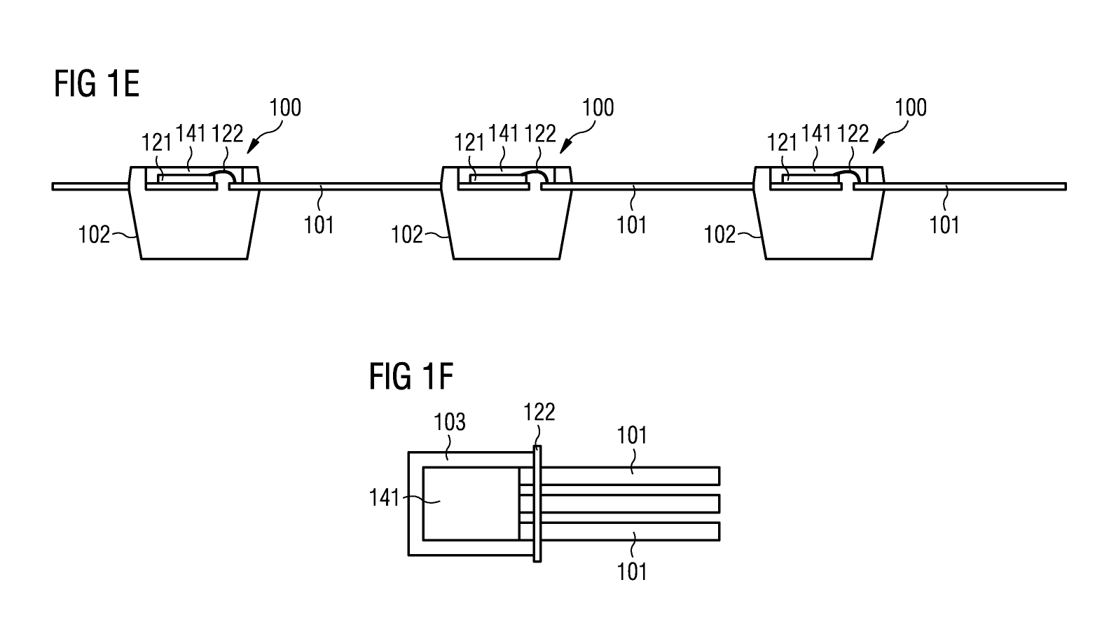

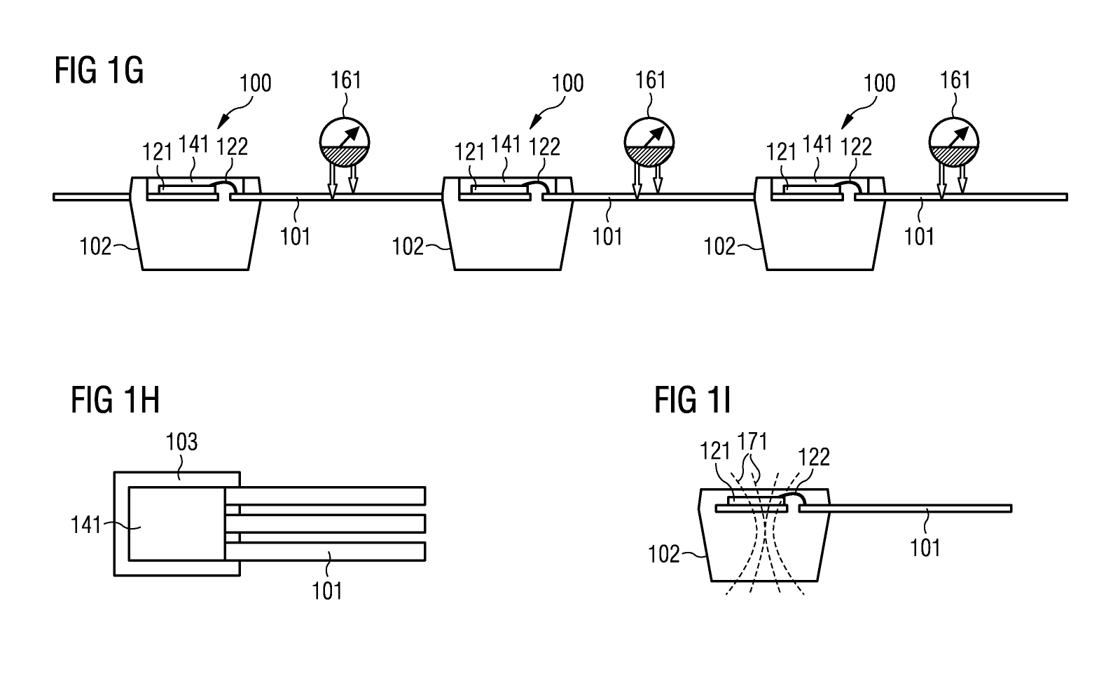

FIG. 1 schematically shows a processing method for a batch of magnet semiconductor assembly groups 100.

In particular, FIG. 1A shows the magnet semiconductor assembly groups 100 in a side view. The magnet semiconductor assembly group 100 comprises a carrier structure 101. Onto the carrier structure 101 a plurality of permanent magnetizable elements 102 of a permanent magnetizable material are formed, e.g. via injection molding, by a moldable or molding, e.g. plastic, material. In particular, each magnet semiconductor assembly group 100 comprises at least one permanent magnetizable element 102. A portion 103 of the moldable material extends through the carrier substrate 101 and forms a back-tapering or undercutting portion. The undercutting portion or undercut 103 fixes the permanent magnetizable elements 102 to the carrier substrate, so that additional glue or adhesive may be omitted. Furthermore, the extending portion or undercutting portion 103 of the permanent magnetizable element 102 forms a kind of shallow recess 104 in the pre-mold of FIG. 1A. Each of the permanent magnetizable element structures 102 may have a size of about 7 mm×7 mm×7 mm for example and thus form a relatively large magnet body or composite which may allow for a strong back-bias magnet field having a remanence between 100 mT and 1000 mT after magnetizing. The permanent magnetizable element structures 102 may be formed or molded, e.g. by thermoplast injection molding, directly to the carrier structure 101 by using metallic permanent magnetizable material and/or non-metallic permanent magnetizable material like plastic material, e.g. polyphenylenesulfide (PPS) or the like.

FIG. 1B shows one of the magnet semiconductor assembly groups 100 of FIG. 1A, in particular a pre-mold or pre-mold structure 111, in a top view. In particular, FIG. 1B shows the carrier structure 101 comprising a dambar 112 which allows to connect or fix several portions of the carrier structure 101 with each other and may as well be used as a stop during the forming or molding of the permanent magnetizable elements or permanent magnetizable element structures 102. Additionally, FIG. 1B shows the undercut portion 103 which is formed around substantially the whole permanent magnetizable element structure when seen from above. A shape of the permanent magnetizable elements may be substantially a truncated pyramid comprising a ridge formed by the undercut portion 103. The undercutting portions 103 may thus form the shallow recess 104 with a flat surface or bottom in the center of the permanent magnetizable element structure 102.

FIG. 1C shows the batch of magnet semiconductor assembly groups 100 of FIG. 1A, wherein a semiconductor chip 121, e.g. an integrated circuit (IC) chip or sensor, is placed on the carrier structure 101 in the shallow recess 104 formed by the permanent magnetizable element so that the semiconductor chip 121 is surrounded by portions of the permanent magnetizable element 102. The semiconductor 121 is electrically connected, e.g. by wire bonding 122, to contact pads or to the carrier structure 101.

FIG. 1D shows the same detail as FIG. 1B however with the semiconductor chip 121 placed in the middle of the pre-mold structure 111 of FIG. 1B.

FIG. 1E shows the batch of the magnet semiconductor assembly groups 100 of FIG. 1C, wherein the semiconductor chip 121 is encapsulated or casted with a top layer 141, e.g. a passivation layer forming a global top.

FIG. 1F shows a single one of the magnet semiconductor assembly groups 100 of FIG. 1E in a top view.

FIG. 1G schematically illustrate the batch of the magnet semiconductor assembly groups 100 of FIG. 1E while an electrical testing of the of the magnet semiconductor assembly groups 100 is performed for the whole batch at the same time or at least while the magnet semiconductor assembly groups are connected to each other by the carrier structure 101, i.e. before a singularizing. However, alternatively the testing may be performed after the singularizing. The testing is schematically indicated by the meters 161 in FIG. 1G. Additionally, the dambars 112 are removed and the carrier structure 101, e.g. the leadframe is cut, e.g. a leadlength-cut may be performed.

FIG. 1H shows a top view of the batch of the magnet semiconductor assembly groups 100 of FIG. 1G.

FIG. 1I schematically illustrates the batch of magnet semiconductor assembly groups 100 after a magnetization which is indicated in FIG. 1I by dashed lines 171, and after the batch of magnet semiconductor assembly groups 100 is singularized.

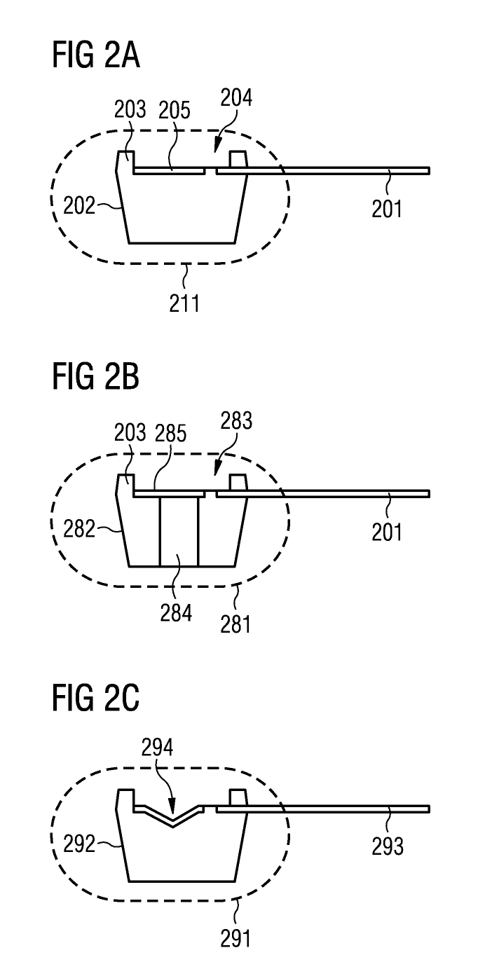

FIG. 2 shows schematic views of examples of shapes of pre-molds according to exemplary embodiments.

FIG. 2A schematically shows a pre-mold 211 which may be used for a back-biasing of a Hall sensor. The pre-mold 211 comprises permanent magnetizable element 202 of permanent magnetizable material which partially extends through a carrier structure 201. In particular, the pre-mold 211 comprises a flat surface 205 enclosed or encircled by an undercut 203 of the permanent magnetizable element 202 extending through the carrier structure 201. The flat surface 205 may form the bottom of a recess 204 formed by the undercut 203 and allows to place a semiconductor, e.g. a sensor, on the flat surface.

FIG. 2B schematically shows another example of a pre-mold 281. The pre-mold 281 comprises a permanent magnetizable element 282 of permanent magnetizable material which as well partially extends through a carrier structure 201 and forms an undercut 203 and a boundary of a recess 283. In the example of FIG. 2B the permanent magnetizable element 202 comprises a hole 284 extending through the permanent magnetizable element 282 so that a hollow cylinder may be formed. Such a hollow cylinder may be formed by using specific adapted thermoplast molding tools and may be used for producing magnet semiconductor assembly groups for cam shaft sensor applications, for example. In particular, the pre-mold 281 comprises a flat surface 285 which allows to place a semiconductor chip, e.g. a sensor, on the flat surface. Additionally or alternatively a semiconductor may be placed in the hole 284. By way of the hole and the form or shape of the hole 284 a resulting magnetic field may be shaped.

FIG. 2C schematically shows another example of a pre-mold 291. The pre-mold 291 comprises a permanent magnetizable element 292 of permanent magnetizable material which as well partially extends through a carrier structure 293. In the example of FIG. 2C the permanent magnetizable element 292 comprises a recess or dent 294 extending into a flat surface of the permanent magnetizable element 292. The recess 294 may have a roof like or pyramid shape and may be formed by an indentation of the carrier structure 293 and may, as well as the hole 284 of FIG. 2B allow for modifying the magnetic field generated by the permanent magnetizable element 292.

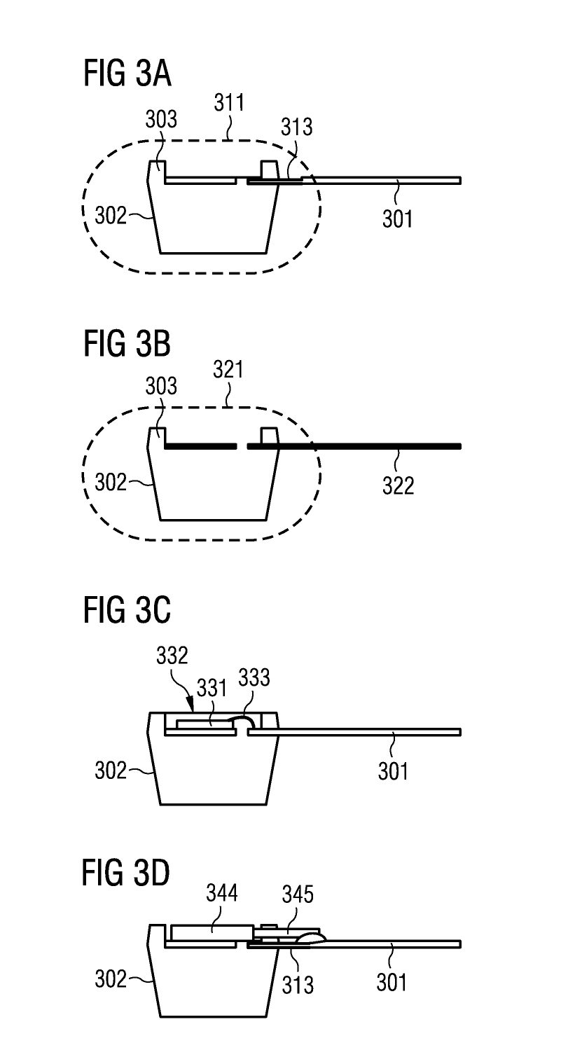

FIG. 3 shows schematic views of examples of carrier structures and semiconductors which can be used in a magnet semiconductor assembly group and which can be used in combination with the examples of pre-molds depicted in FIG. 2.

In particular, FIG. 3A shows a pre-mold 311 similar to the one depicted in FIG. 2A. The pre-mold 311 comprises a carrier structure 301 and a permanent magnetizable element 302 comprising a permanent magnetizable material, e.g. a mixture of a base or main compound, e.g. a mold material, which may be electrically conductive, and a permanent magnetizable compound like PPS or a ferromagnetic material. The permanent magnetizable element 302 partially extends through the carrier structure 301 and forms an undercut 303. Additionally, the pre-mold 311 of FIG. 3A comprises an electrically insulation layer 313. The insulation layer 313 is arranged between the permanent magnetizable element 302 and the carrier structure 301, e.g. a leadframe, insulating the two portions from each other. For example, the insulating layer 313 may be formed by a protection resin formed in the permanent magnetizable element or magnet body 302. The insulating layer may be advantageous in case the carrier structure 301 as well as the permanent magnetizable element 302 is electrically conductive.

In particular, FIG. 3B shows a pre-mold 321 similar to the one depicted in FIG. 2A. The pre-mold 321 comprises a carrier structure 322, and a permanent magnetizable element 302 comprising a permanent magnetizable material, e.g. a mixture of a base or main compound, e.g. a mold material, which may be electrically conductive or insulating, and a permanent magnetizable compound like PPS or a ferromagnetic material. The permanent magnetizable element 302 partially extends through the carrier structure 301 and forms an undercut 303. According to the example of FIG. 3B the carrier structure 322 is formed by a circuit board, a printed circuit board or flexible print materials instead of a leadframe.

FIGS. 3C and 3D schematically shows two different types of semiconductor chips, IC chips or sensors which can be used in a magnet semiconductor assembly group comprising a permanent magnetizable element 302 and a carrier structure 301. In particular, FIG. 3C schematically depicts the use of an unpacked semiconductor chip 331 which is encapsulated by a passivation layer 332 and bonded to the carrier structure via wire bonding 333. FIG. 3D schematically depicts the use of an already packaged sensor or sensor module 344 and bonded to a carrier structure 301 via wire bonding 345.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of manufacturing pre-molds for magnet semiconductor assembly groups, the method comprising:
forming a plurality of permanent magnetizable elements on a carrier structure in a sensor-free area of the carrier structure by applying a permanent magnetizable molding material on the carrier structure.

2. The method according to claim 1, wherein at least one of the plurality of permanent magnetizable elements is a three dimensional element, wherein the extension of the element is in a first dimension in the range between 2.5 mm and 25 mm, in a second dimension in the range between 2.5 mm and 25 mm and in a third dimension in the range between 2.5 mm and 25 mm.

3. The method according to claim 1, wherein the permanent magnetizable material comprises electrically conductive material.

4. The method according to claim 3, further comprising forming an electrically insulating layer between the carrier structure and at least one of the plurality of permanent magnetizable elements.

5. The method according to claim 1, further comprising singularizing the plurality of permanent magnetizable elements.

6. The method according to claim 1, further comprising magnetizing at least one of the plurality of permanent magnetizable elements.

7. The method according to claim 1, wherein at least one of the plurality of permanent magnetizable elements comprises a recess.

8. The method according to claim 1, wherein at least one of the plurality of permanent magnetizable elements comprises a hole.

9. The method according to claim 1, wherein at least one of the plurality of permanent magnetizable elements is formed on a first main surface of the carrier structure and comprises a portion which extends through the carrier structure onto a second opposite main surface of the carrier structure.

10. The method according to claim 1, further comprising arranging at least one semiconductor chip at the plurality of permanent magnetizable elements.

11. The method according to claim 10, further comprising:
encapsulating the at least one semiconductor chip arranged at the plurality of permanent magnetizable elements.

12. Pre-mold array for magnet semiconductor assembly groups, the pre-mold array comprising:
a carrier structure, and
a plurality of permanent magnetizable elements of a permanent magnetizable material formed onto the carrier structure by an adhesive-free process,
wherein the plurality of permanent magnetizable elements are formed in a sensor-free area of the carrier structure.

13. The pre-mold array according to claim 12, wherein each of the plurality of permanent magnetizable elements is a three dimensional element, wherein the extension of the element is in a first dimension in the range between 2.5 mm and 25 mm, in a second dimension in the range between 2.5 mm and 25 mm and in a third dimension in the range between 2.5 mm and 25 mm.

14. The pre-mold array according to claim 12, wherein the carrier structure is an electrically conductive carrier structure.

15. The pre-mold array according to claim 14, further comprising an electrically insulating layer arranged between the electrically conductive carrier structure and each of the plurality of permanent magnetizable elements of permanent magnetizable material.

16. The pre-mold array according to claim 12, wherein the permanent magnetizable material is one of the group consisting of electrically conductive and electrically insulating.

17. The pre-mold array according to claim 12, wherein the permanent magnetizable material is electrically insulating.

18. The pre-mold array according to claim 12, wherein the permanent magnetizable material is electrically conductive.

19. The pre-mold array according to claim 12, wherein the at least one of the plurality of permanent magnetizable elements comprises an undercut engaging behind the carrier structure.

20. A method of manufacturing a magnet semiconductor assembly group, the method comprising:
molding a plurality of permanent magnetizable elements of a permanent magnetizable material on a carrier structure,
placing a semiconductor chip at one of the plurality of permanent magnetizable elements of a permanent magnetizable material.
